(19) United States
(12) Patent Application Publication
(10) Pub. No.: US 2002/0085600 A1
(43) Pub. Date: Jul. 4, 2002

(54) Method of high speed direct-modulation for common-cathode laser array

(76) Inventor: Taewon Jung, Malabar, FL (US)

Correspondence Address: CHRISTIE, PARKER & HALE, LLP, P.O. BOX 7068, PASADENA, CA, 91109-7068, US

(21) Appl. No.: 10/081,622

(22) Filed: Feb. 20, 2002

Related U.S. Application Data
(63) Continuation of application No. 10/012,783, filed on Nov. 6, 2001.
(60) Provisional application No. 60/246,325, filed on Nov. 6, 2000.

(51) Int. Cl. H01S 3/13; H01S 5/00

(52) U.S. Cl. 372/38.02; 372/43

(57) ABSTRACT

A drive circuitry that drives a number of vertical cavity surface emitting lasers having a common cathode. The drive circuitry includes a modulator and a dummy laser. The modulator controls the vertical cavity surface emitting lasers. A summed modulation and bias current is directed to one of the vertical cavity surface emitting lasers to turn on the laser. The modulation current is pulled away from the vertical cavity surface emitting laser to turn off the laser.

### CROSS-REFERENCE TO RELATED APPLICATIONS

This application is a continuing application of U.S. patent application Ser. No. 10/012,783 filed Nov. 6, 2001 which claims the benefit of U.S. provisional application No. 60/246,325 filed Nov. 6, 2000 which is hereby incorporated by reference as if set forth in full herein.

### BACKGROUND

The present invention relates generally to semiconductor lasers, and, more particularly, to methods and circuits for modulating data communication lasers.

Semiconductor lasers are widely used in high speed data communications. Modulated light from the lasers are used to carry information through fiber optic lines. For some data formats, generally, when a laser emits light the data value is considered a logical one and when the laser is largely off the data value is considered a zero.

Vertical cavity surface emitting lasers (VCSELs) are one type of laser used in data communication networks. VCSELs are generally relatively easy to manufacture using semiconductor processes and light from VCSELs is emitted from the VCSELs' surfaces, rather than from their edges. Arrays of VCSELs are able to be relatively easily manufactured on a common substrate, with the common cathode.

Typically, drive circuitry for VCSELs provide a VCSEL with sufficient current to turn “on”, i.e., cause the VCSEL to emit light. Likewise, the drive circuitry removes or prevents current from flowing to the VCSEL to turn the VCSEL “off”, i.e., cause the VCSEL to not emit light, or more generally, emit light at a reduced intensity. In high speed data communications, for directly modulated VCSELs, the drive circuitry should be able to drive the individual anodes of the individual VCSELs rapidly in order to switch the VCSEL on and off at high rates of speed.

However, competing desired performance factors, such as speed, low power, and jitter, often causes difficulties in supplying a high speed current to the VCSEL. Other considerations that causes difficulties include a low power supply voltage, a high VCSEL forward voltage threshold, varying bias voltage and temperature and variations in the manufacturing of the VCSEL. Also, the VCSEL array having a common cathode and being able to control each individual VCSEL separately further introduces difficulties.

### SUMMARY OF THE INVENTION

The present invention provides a system and method for driving a number of semiconductor lasers such as a vertical cavity service emitting laser. In one embodiment, a drive circuitry is provided that drives a plurality of semiconductor lasers with each laser having a cathode and each cathode of the plurality of semiconductor lasers being common to a substrate. The driver circuitry includes a modulator which is coupled to one of the plurality of semiconductor lasers and controls the one of the plurality of semiconductor lasers and generates a modulation current. A dummy laser is also provided that is coupled to the one of the modulator. The modulator is configured to generate a bias current and a summed modulation and bias current. In one aspect of the invention, a transistor switch is provided that directs the summed modulation and bias current to flow to one of the plurality of semiconductor lasers. In another aspect of the invention, the transistor switch directs the modulation current to flow to the dummy laser. In a further aspect of the invention, a capacitor provides a discharge path for the transistor switch. The capacitor is added for higher speed.

In another embodiment, a method of driving the plurality of semiconductor lasers each having a cathode is provided. Each cathode of the plurality of semiconductor lasers are common to a substrate. Also, a bias current is supplied to one of the plurality of semiconductor lasers. A modulation current is supplied. A summed modulation and bias current is provided to one of the plurality of semiconductor lasers via a first transistor switch to turn on the one of the plurality of semiconductor lasers. Also, a bias current is provided to the one of the plurality of semiconductor lasers via a second transistor switch to turn off the one of the plurality of semiconductor lasers.

Many of the attendant features of this invention will be more readily appreciated as to the same becomes better understood by reference to the following detailed description and considered in connection with the accompanying drawings.

### BRIEF DESCRIPTION OF THE DRAWINGS

FIG. 1 illustrates a block diagram of one embodiment of a modulator; and

FIG. 2 illustrates a circuit diagram of one embodiment of the modulator of FIG. 1.

### DETAILED DESCRIPTION

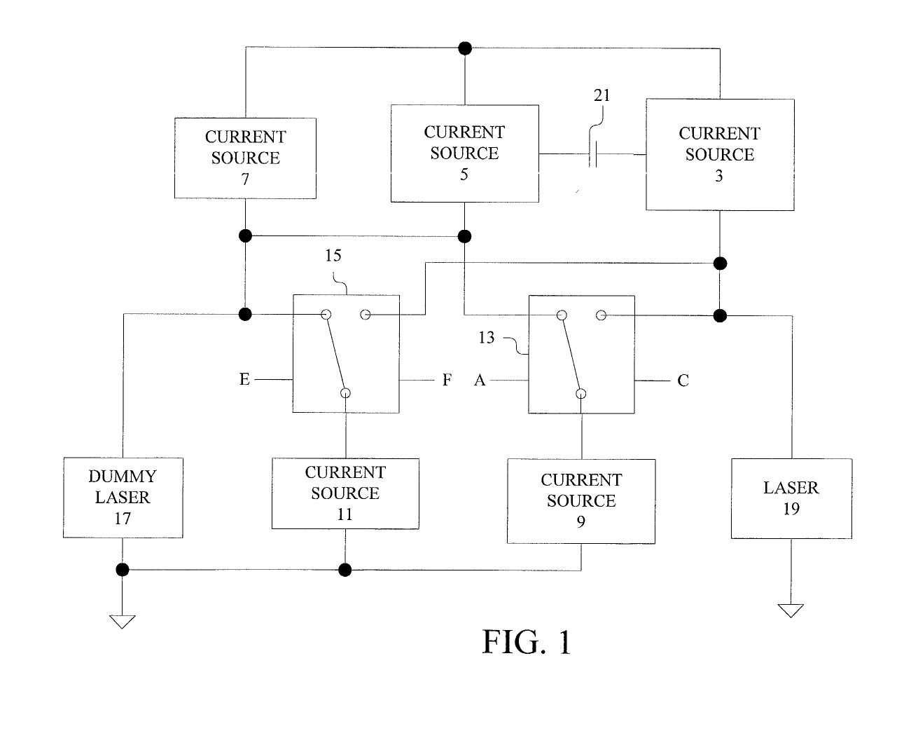

FIG. 1 illustrates a block diagram of one embodiment of a modulator for driving a semiconductor laser having a cathode connected to a substrate. The modulator includes current sources 3, 5, 7, 9 and 11, switches 13 and 15, dummy laser 17, and a laser 19. A capacitor, C1, connects current source 3 to current source 5 for speed improvement.

When switches or switch circuits 13 and 15 are set at the left position as shown in FIG. 1, the current source 3 provides a summed bias and modulation current to the laser 19. As such, the laser will emit light corresponding to a logic one. Control inputs A and C determines the direction of switch 13 while control inputs E and F control switch 15. A modulation current from current source 5 flows to current source 9 through switch 13. A differential current flows into dummy laser 17. The current from current source 7 flows into current source 11 through switch 15.

When the switch 13 is flipped to the right position and the switch 15 remains at left position, the current from current source 3 minus the current pulled by current source 9 flows in to laser 19. The current source 9 provides a modulation current. The laser is turned off since only bias current is being provided to the laser. Thus, the laser emits a dim light into a fiber optical cable corresponding to logic zero. During this turn-off transient, switch 15 is flipped to the right position and stays there for a short period and returns back to left position. This dynamic pulls current from laser 19 with the help of current source 11. As such, a fast turn-off transient by removing the stored charge from the laser 19 forcibly is provided.

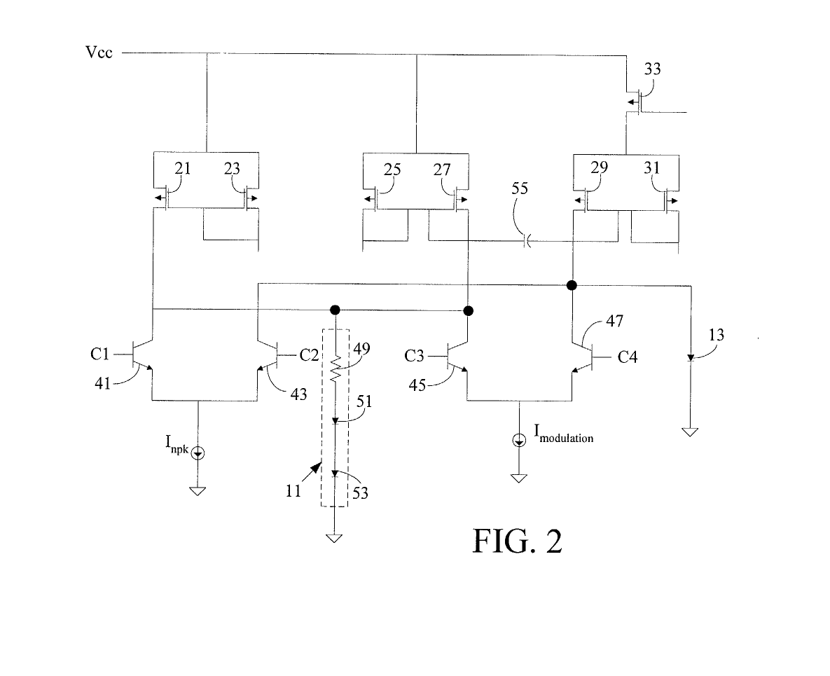

FIG. 2 illustrates a circuit diagram of one embodiment of the modulator of FIG. 1. The modulator includes 7 P-channel FETs 21, 23, 25, 27, 29, 31 and 33. The sources of FETs 21, 23, 25, 27 and 33 are coupled to a reference voltage V_{cc}. The sources of FETs 29 and 31 are coupled to the drain of FET 33. The gates of FETS 21 and 23 are coupled together and the drain of FET 23 is coupled to the gates of FETs 21 and 23. As such, FETs 21 and 23 act as a current mirror providing a negative peaking current to bipolar junction transistor (BJT) 41 or dummy laser 11, both coupled to FET 21 via its drain.

Similarly, the gates of FETs 25 and 27 are coupled together and the drain of FET 25 is coupled to the gates of FETs 25 and 27. FETs 25 and 27 act as a current mirror providing a modulation current to BJT 45 or dummy laser 11, both being coupled to FET 27 via its drain. The bases of BJTs 41 and 45 are respectively coupled to control inputs C1 and C3. In one embodiment, the value of control input C1, e.g., high or low, is generally high, transitioning to low for brief periods when control input C3 goes low. When control inputs C1 and C3 are high, respective BJTs 41 and 45 turn on creating paths to current sources, Iₙₚₖ and I_{modulation}. Thus, negative peaking current flows to BJT 41 and modulation current flows to BJT 45. On the other hand, when control input C1 and C3 are low, respective BJTs 41 and 45 turn off, and thus modulation current and negative peaking current flows to resistor 49 of dummy laser 11. Resistor 49 is also coupled to diode 51 which is coupled to diode 53.

Collectors of BJTs 43 and 47 are also coupled together and to the anode of laser diode 13. Also, the drain of FET 29 is coupled to the collectors of BJTs 43 and 47 and laser diode 13. The gate of FET 29 is coupled to the gate and drain of FET 31. Sources of FETs 29 and 31 are also coupled together. Together FETs 29 and 31 act as a current mirror providing a summed modulation and bias current. The bases of BJTs 43 and 47 are respectively coupled to control inputs C2 and C4 which form with control inputs C1 and C3, respectively, differential inputs. In one embodiment, control input C2 is briefly set high right after control input C4 is set from low to high. When control input C2 is high, BJT 43 turns on creating a path to ground and thus draws negative peaking current from laser diode 13. When control input C4 is high, BJT 47 turns on creating a path to I_{modulation} and thus draws modulation current from FET 29. However, when control input C2 is low, BJT 43 turns off and thus no negative peaking current is drawn from laser diode 13. Also, when control input C4 is low, BJT 47 turns off and thus modulation current is not drawn from FET 29. As such, when BJTs 43 and 47 are off, a summed modulation and bias current flows to laser diode 13 thus turning laser diode 13 on, i.e., laser diode 13 emits light.

On the other hand, when both BJTs 43 and 47 turn on, modulation current and negative peaking current is drawn away from laser diode 13. As modulation and negative peaking current is drawn away from laser diode 13, laser diode 13 turns off although bias current still flows to laser diode 13. BJT 43 by drawing negative peaking current away from the laser diode 13, assists in increasing the turn off transient. In other words, the laser diode 13 when turned on stores an electric charge. Removing the stored charge affects the turn off time of the laser. The amount of time or time period required to remove the charge from the laser diode, i.e., the turn off transient, is reduced by the BJT 43 drawing or pulling the negative peaking current from laser diode 13. During the turn off transient, BJT 41 is off and thus current from FETs 21 and 23 flows to the dummy laser 11.

In one embodiment, the capacitor 55 is coupled to gates of FETs 25 and 27 and gates of FETs 29 and 31. As such, gates of FETs 25 and 27 are coupled to gates of FETs 29 and 31, via the capacitor 55. The capacitor provides an AC discharge path through which charge built up at the gate of FET 29 flows. When the laser diode is turning on, voltage at the laser diode rises rapidly and thus sends charge into the gate of FET 29. This charge lowers the source to gate voltage experienced by FET 29 which limits the drain to source current of FET 29. Capacitor 55 thus provides a path for the charge sent by BJT 47 to be discharged by BJT 45.

In one embodiment, the drain of FET 33 is coupled to the sources of FETs 29 and 31. The source of FET 33 is coupled to a reference voltage and its gate is coupled to a shutdown input. As such, when the shutdown input is high, the FET 33 turns off thus severing the path of the sources of the FETs 29 and 31 to the reference voltage. Hence, no current is able to be supplied to laser diode 13 and thus laser diode 13 turns off. On the other hand, when the shutdown input is low, FET 33 turns on and thus current is able to flow to laser diode 13 via FETs 29 and 31.

Accordingly, the present invention provides a method and system of controlling the modulation of a vertical cavity surface emitting laser array with a common-cathode. Although this invention has been described in certain specific embodiments, many additional modifications and variations would be apparent to those skilled in the art. It is therefore to be understood that this invention may be practiced otherwise than as specifically described. Thus, the present embodiments of the invention should be considered in all respects as illustrative and not restrictive. The scope of the invention to be determined by the appended claims, their equivalents, and claims supported by the specification, rather than the foregoing description.

What is claimed is:

1. A drive circuitry driving a plurality of semiconductor lasers each having a cathode, each cathode of the plurality of semiconductor lasers being common to a substrate, the drive circuitry comprising:
a modulator coupled to one of the plurality of semiconductor lasers and configured to generate a modulation current to control the one of the plurality of semiconductor lasers;
a dummy laser coupled to the modulator; and
wherein the modulator is configured to sum modulation and bias currents and mirror the summed modulation and bias current.

2. The drive circuitry of claim 1 further comprising a transistor switch directing the summed modulation and bias current to flow to one of the plurality of semiconductor lasers.

3. The drive circuitry of claim 1 further comprising a transistor switch directing the modulation current to flow to the dummy laser.

4. The drive circuitry of claim 1 further comprising a transistor switch directing a negative peaking current to flow to the dummy laser.

5. The drive circuitry of claim 2 comprising a capacitor providing a discharge path for the transistor switch.

6. The drive circuitry of claim 2 wherein the dummy laser balancing operating conditions of the transistor switch to prevent the transistor switch from going into saturation.

7. The drive circuitry of claim 1 wherein the dummy laser provides a drainage for excess current flow.

8. The drive circuitry of claim 1 further comprising a shut-down transistor restricting current flow into the laser.

9. The drive circuitry of claim 1 wherein the plurality of semiconductor lasers are vertical cavity surface emitting lasers.

10. A method of driving a plurality of semiconductor lasers each having a cathode, each cathode of the plurality of semiconductor lasers being common to a substrate, the method comprising:
supplying a modulation current;
providing a summed modulation and bias current to one of the plurality of semiconductor lasers via a first transistor switch to turn on the one of the plurality of semiconductor lasers; and
providing a bias current to the one of the plurality of semiconductor lasers via a second transistor switch to turn off the one of the plurality of semiconductor lasers.

11. A drive circuitry comprising:
a plurality of semiconductor lasers;
means for supplying a modulation current;
means for imitating a characteristic of a semiconductor laser;
means for controlling flow of the modulation current to a dummy laser and controlling the flow of the modulation current to the means for imitating a characteristic of a semiconductor laser; and
means for drawing increased current from the one of the plurality of semiconductor lasers at laser turn off.
